(19) United States
(12) Patent Application Publication
(10) Pub. No.: US 2026/0215286 A1
(43) Pub. Date: Jul. 23, 2026

(54) SIGNAL INTEGRITY IMPROVEMENT USING INDUCTOR IN SEMICONDUCTOR PACKAGE

(71) Applicant: Samsung Electronics Co., Ltd., Suwon-si (KR)

(72) Inventor: Shindeok KANG, San Diego, CA (US)

(21) Appl. No.: 19/178,850

(22) Filed: Apr. 14, 2025

Related U.S. Application Data
(60) Provisional application No. 63/713,036, filed on Oct. 28, 2024.

(51) Int. Cl. H10W 44/00; H10W 42/60; H10W 72/50

(52) U.S. Cl. CPC H10W 44/501; H10W 42/60; H10W 72/541

(57) ABSTRACT

A system and a method for an inductor circuit are described. The inductor circuit includes a first inductor and a first bonding wire. The first inductor is configured to be embedded in a first die connected to a die first pad. The first die is bonded to a substrate. The first bonding wire is configured to connect the substrate to the die first pad. The first bonding wire has a first parasitic inductance. The first inductor has a first inductance. a non-target on-die termination (ODT) is used to create a reflection signal path from the ODT to a receiver.

### CROSS-REFERENCE TO RELATED APPLICATION

This application claims the priority benefit under 35 U.S.C. § 119(e) of U.S. Provisional Patent Application Ser. No. 63/713,036 filed on Oct. 28, 2024, the disclosure of which is incorporated by reference in its entirety as if fully set forth herein.

### TECHNICAL FIELD

The disclosure generally relates to semiconductor. More particularly, the subject matter disclosed herein relates to signal integrity in semiconductor packages.

### BACKGROUND

Signal integrity refers to the quality of a signal as it travels through a transmission line or a signal path. It is a measure of how well a signal remains unchanged throughout the path of travel, whether it is a communication medium such as cables or conductive wires or a device or circuit. Due to several factors including impedance mismatches, crosstalk, inter symbol interferences (ISI), noise, and reflections, the signal quality of a signal often worsens as the signal travels from one location to another in a system. The effect is even more pronounced when the bandwidth of the system increases.

Existing techniques to improve signal quality of high-frequency signals have a number of drawbacks. Receiver or transmitter equalizers such as feed-forward equalizer (FFE), decision feedback equalizer (DFE), or continuous time linear equalizer (CTLE) are designed to compensate for distortions cause by insertion losses, ISI, crosstalk, and other sources of degradation. These equalizing devices, however, involve complex circuits, occupy large areas, and consume more power.

### SUMMARY

To overcome these issues, systems and methods are described herein for a technique of improving signal quality in semiconductor packages, devices and circuits. The inductor circuit includes a first inductor and a first bonding wire. The first inductor is configured to be embedded in a first die connected to a die first pad. The first die is bonded to a substrate. The first bonding wire is configured to connect the substrate to the die first pad. The first bonding wire has a first parasitic inductance. The first inductor has a first inductance. At least one of the first inductance and a sum of the first inductance and the first parasitic inductance contributes to an effective inductance to improve signal integrity for signals propagating through the first die.

### BRIEF DESCRIPTION OF THE DRAWINGS

In the following section, the aspects of the subject matter disclosed herein will be described with reference to exemplary embodiments illustrated in the figures, in which:

FIG. 1 is a block diagram illustrating a system according to an embodiment.

FIG. 2 is a diagram illustrating a semiconductor package according to an embodiment.

FIG. 3A is a diagram illustrating a connection configuration of a single die package according to an embodiment.

FIG. 3B is a diagram illustrating an inductor circuit in a single die package according to an embodiment.

FIG. 4A is a diagram illustrating a direct bonding connection in a die-stacked package according to an embodiment.

FIG. 4B is a diagram illustrating an inductor circuit using the direct bonding connection in a die-stacked package according to an embodiment.

FIG. 5A is a diagram illustrating a cascade connection in a die-stacked package according to an embodiment.

FIG. 5B is a diagram illustrating an inductor circuit using the cascade connection in a die-stacked package according to an embodiment.

FIG. 6 is a diagram illustrating performance curves as functions of inductance at various data rates according to an embodiment.

FIG. 7 is a diagram illustrating performance curves as functions of inductance at various connection configurations according to an embodiment.

FIG. 8 is a diagram illustrating a configuration of an inductor with a switch to adjust inductance according to an embodiment.

FIG. 9A is a diagram illustrating a configuration of an inductor circuit with switch in a single-die package according to an embodiment.

FIG. 9B is a diagram illustrating a configuration of an inductor circuit with switch in a die-stacked package according to an embodiment.

FIG. 10 is a flowchart illustrating a first part of a process of connecting an inductor circuit according to an embodiment.

FIG. 11 is a flowchart illustrating a second part of the process of connecting an inductor circuit according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The disclosure describes an inductor circuit to improve signal integrity in a semiconductor die. The method improves signal integrity by using the resonance of coil inductance and load capacitance. By using inductive peaking, the attenuation portion of the signal may be improved, thereby improving signal integrity. By selecting an appropriate on-die termination (ODT) resistor, the parasitic inductance of the bond wire may be utilized to reduce the inductance of the coil, thereby reducing the area.

The inductor circuit may include a single-die configuration or a stacked-die configuration. For a single-die configuration, the inductor circuit includes a first inductor and a first bonding wire. The first inductor has a first inductance and is embedded in a first die bonded on a substrate. The first bonding wire connects a pad on the substrate to a die first pad of the first die. The first bonding wire has a first parasitic inductance. At least one of the first inductance and a sum of the first inductance and the first parasitic inductance contributes to an effective inductance to improve signal integrity for signals propagating through the first die. For a stacked-die configuration, the inductor circuit includes a second inductor embedded in a second die which is bonded to the top surface of the first die. The second inductor has second inductance. Two connection configurations are available: a direct bonding connection and a cascade bonding connection. In the direct bonding connection, two bonding wires are connected to the first die and the second die from the same connection point on the substrate. In the cascade bonding connection, a first bonding wire connects the substrate to the die first pad and a second bonding wire connects the die first pad to a die second pad of the second die. The second bonding wire has a second parasitic inductance. The effective inductance of the inductor circuit in the direct bonding connection is equal to the sum of the first inductance, the second inductance, the first parasitic inductance and the second parasitic inductance. The effective inductance of the inductor circuit in the cascade bonding connection is equal to the sum of the first inductance, the second inductance, and the second parasitic inductance. The inductance of the inductor may be adjusted using a switch. By varying the inductance, the inductor circuit may provide optimal performance in improving signal integrity.

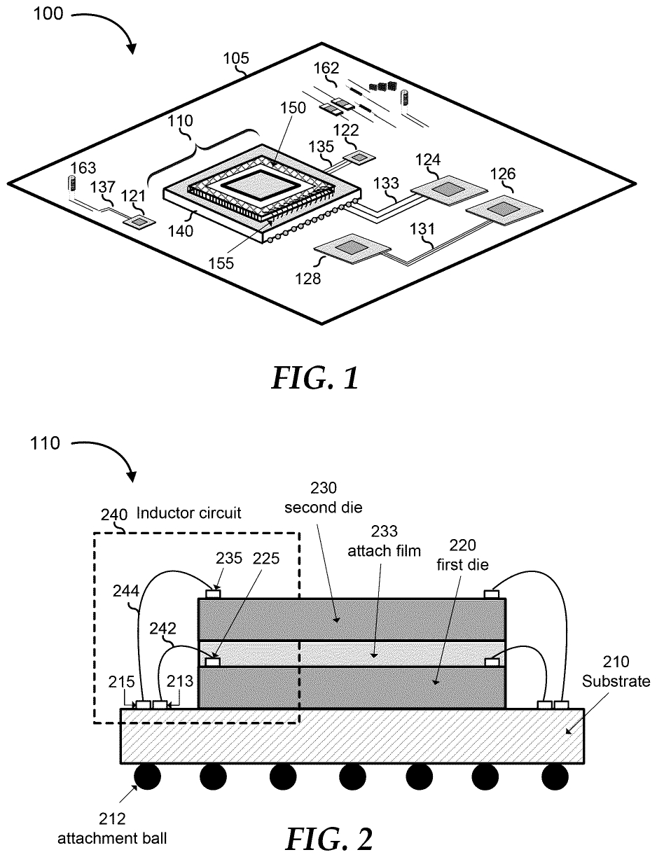

FIG. 1 is a block diagram illustrating a system 100 according to an embodiment. The system 100 includes a printed circuit board 105, a semiconductor package 110, integrated circuits 121,122, 124, 126, and 128, discrete components 162 and 163, and traces 131. 133. 135, and 137. The system 100 may include more or less than the above components. The above components are for illustrative purposes and do not represent any particular arrangements.

The printed circuit board (PCB) 105 is a board that holds and connects various components of an electronic circuit or system. It may be made of a non-conductive material such as fiberglass or epoxy. The components on the PCB 105 may be any components, including electronic, mechanical, optical, digital, or any analog. The semiconductor package 110 is an integrated circuit packaged in any type of package including through hole packages, surface mount packages, chip carrier packages (e.g., bump chip carrier, leadless chip carrier), pin grid arrays, flat packages, small outline packages, chip scale packages, ball grid array. In one embodiment, the semiconductor package accommodates die stacking, including 2.5D packaging, 3D packaging, stacked-die chip scale packages (CSPs). It may be a device that performs any function such as central processing unit (CPU), graphics processing unit (GPU), memories (e.g., dynamic random-access memories, flash memories), applications specific integrated circuits (ASICs), field programmable gate arrays (FPGAs), or a combination of these devices. Similarly, the integrated circuits 121,122, 124, 126, and 128 may be any of these devices. The discrete components 162 and 163 may be any types of discrete components including resistors, capacitors, inductors, optical devices, electromechanical devices, or specially designed devices (e.g., sensors, pressure sensors, image sensors). The traces or lines 131, 133, 135, and 137 are conductive connecting elements that connect the components together. They are typically made of copper or gold etched into the PCB 105.

When powered up, the components on the PCB 105 may consume power and transmit and receive signals. The signals may travel from any source locations to any destination locations through traces or wires. During their propagation through traces, wires, or any other medium, the signals may be distorted or degraded due to any of several factors such as noise, impedance mismatch, channel losses, inter symbol interferences (ISI), crosstalk, ground bounce, etc. As the frequency or data rate increases, the effects of these factors become more pronounced. Signal integrity (SI) refers to the ability of a signal to propagate through a transmission line or communication channel without distortion. Methods to improve signal quality may include proper grounding and decoupling, impedance matching, minimizing trace lengths, and equalization. These techniques are widely used in high-frequency applications, especially when devices are packaged in highly dense packages and have stacked dies like the semiconductor package 110. In addition, equalizers such as feed-forward equalizer (FFE), decision feedback equalizers (DFE), continuous time linear equalizers (CTLEs), consume large power and occupy large areas. In one embodiment, the semiconductor package 110 implements a simple circuit that is based on the concept of passive equalization using coils or inductors and does not consume much power and therefore are suitable for low-power applications such as mobile devices, cameras, and smart phones.

Signal integrity may be determined by using a suitable tool. Examples of tools for determining or measuring signal integrity include vector network analyzer (VNA), oscilloscopes to analyze eye diagrams, time-domain reflectometer, and near-field probe. Eye diagram analysis is often used to analyze signal integrity. An eye diagram, also called an eye pattern, is a way to view the response of a digital circuit over time. It shows multiple signal cycles overlaid on each other. Typically, the height or the width the open eye is used to assess the quality of the SI. In the following description, the voltage representing the eye height is used to quantify the SI. When a signal encounters dielectric loss, conductor loss, radiation loss, or impedance mismatch, the signal can experience significant reflections and distortions, negatively impacting signal integrity. To get a quantitative view of signal integrity performance, other measurements can be applied to the eye-diagram pattern, including eye height, eye width, signal amplitude, and slew rate. The measured values can then be compared with the standard specifications.

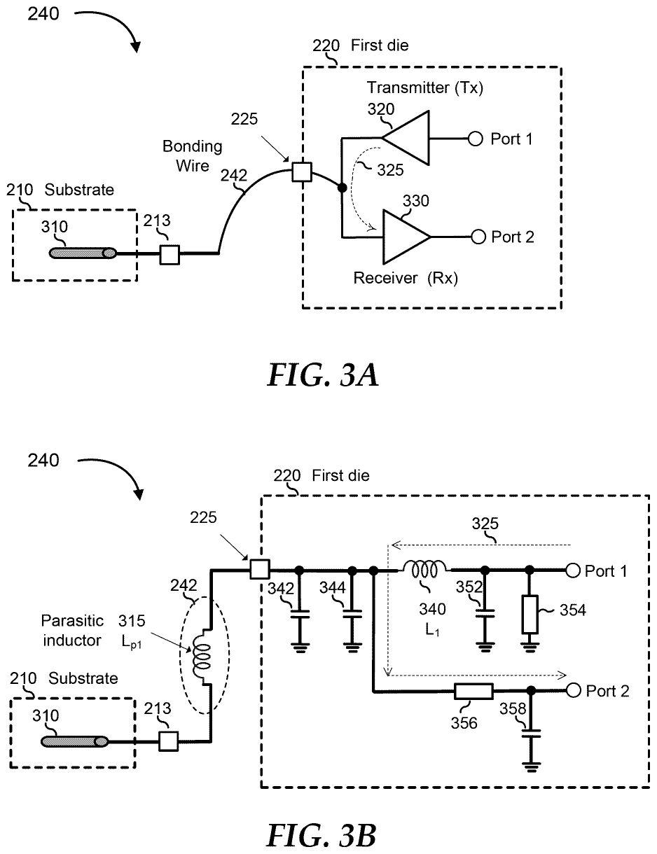

FIG. 2 is a diagram illustrating the semiconductor package 110 shown in FIG. 1 according to an embodiment. The package 110 includes a substrate 210, a first die 220, and a second die 230. The package 110 may include more or less than the above component. In one embodiment, the package 110 includes only a single die, the first die 220. In another embodiment, the package 110 includes more than one die, including the first die 220 and the second die 230. The package 110 may also include three dies, four dies, etc., stacked on, or positioned adjacent to, each other. Accordingly, in the following, the discussion is about stacked dies with two dies, but other configurations are possible. For example, in a single die configuration, the second die 230 and the associated pad and wires may not be present.

The substrate 210 provides a platform for the first die 220 in a single die package or the first die 220 and the second die 230 in a two-die package, to be mounted on. It has attachment balls 212 to attach to a platform such as a printed circuit board. The substrate 210 may have a network of vias and conductive layers to connect the solder bumps on the dies, for electrical communication. It may contain a package channel that provides a medium for signal transmission. It may have substrate pads 213 and 215. The pads 213 and 215 are small areas of a conductive material (e.g., copper) to provide a point of electrical connection. In one embodiment, the first and second substrate pads 213 and 215 may be connected together to become a single connection point. The bonding between the first die 220 and the substrate 210 may be done in several ways. Examples of bonding methods include epoxy die bonding, ultraviolet (UV) light, ultrasonic, thermocompression, metallic sinter. The second die 230 is stacked on the first die 220 in several ways. In one embodiment, the second die 230 is bonded on an attachment film or an interposer 233. The first die 220 and the second die 230 may be of any size. In one embodiment, they have the same size as the attachment film 233.

A die first pad 225 is an electrical connection on the surface of the first die 220. A first bonding wire 242 may be connected to the substrate 210 at the substrate pad 213 and to the first die 220 at the die first pad 225. A second bonding wire 244 may be connected to the substrate 210 at the substrate pad 215 and to the second die 230 at a die second pad 235. The first bonding wire 242 or the second boding wire 244 is a thin metal wire that connects the substrate to the corresponding die. The bonding wires may be made of materials from combinations of gold (Au), copper (Cu), aluminum (Al), and silver (Ag). Other materials may also be used including such as palladium (Pd), platinum (PT), nickel (NI), and silicon carbide (SiC). The first bonding wire 242 or the second boding wire 244 may introduce inductance at high frequencies. It may be modeled as a lumped or parasitic inductance in series with the resistance. The inductance associated with the first bonding wire 242 or the second boding wire 244 depends on several factors including wire diameter, wire metal, wire length, wire thickness, operational frequency, height above the substrate, and separation distance between wires. These factors are often not known in advance. Therefore, it is difficult to determine with accuracy the parasitic inductance. Parasitic inductance often causes undesirable effects to signal integrity at high frequencies by causing signal reflections, ringing, and increased power dissipation. Accordingly, it is desirable to compensate for the parasitic inductance with inductors having controllable inductance and with suitable connection patterns.

The package 110 may also be considered as including an inductor circuit 240 which includes the first and second bonding wires 242 and 244 and circuitries inside the first and second dies 220 and 230. The inductor circuit 240 improves signal integrity within the package 110 by having connection patterns that provide a suitable effective inductance.

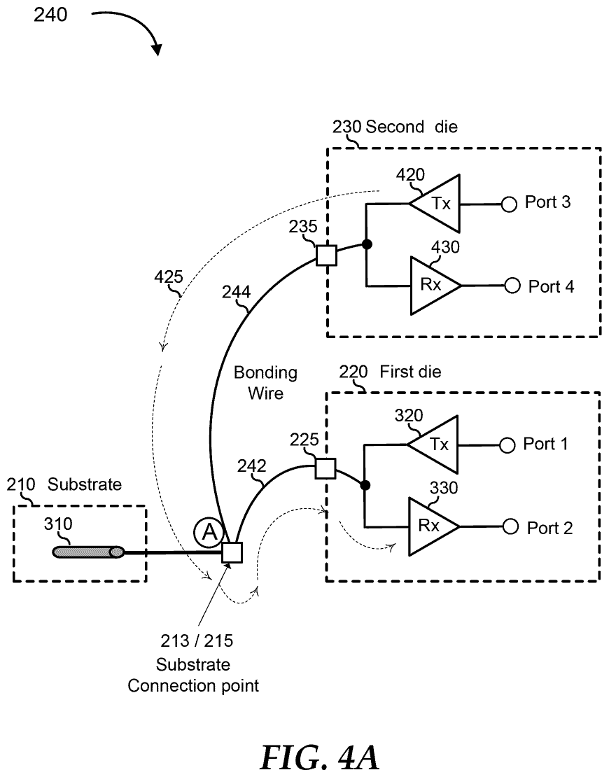

FIG. 3A is a diagram illustrating a connection configuration of a single die package according to an embodiment. The connection configuration includes the bonding wire 242, a transmitter 320 and a receiver 330. The connection configuration may include more or less than then above components.

The bonding wire 242 is connected to the substrate pad 213 which may be connected to a package channel 310. The package channel 310 is a channel, virtual or physical, that carries a signal transmission on the substrate 210. The bonding wire 242 connects the substrate 210 to the die first pad 225. The die first pad 225 is connected to circuitry embedded in the first die 220. The first die 220 has a transmitter port 1 and a receiver port 2. The transmitter 320 sends a signal to a host. When the host sends the signal to the receiver 330, the transmitter 320 acts like an on-die termination (ODT). A path 325 is a reflection path from the ODT 354 (in FIG. 3B) to the receiver port 2.

FIG. 3B is a diagram illustrating the inductor circuit 240 shown in FIG. 2 in a single die package according to an embodiment. The inductor circuit 240 includes an inductor 340 and the first bonding wire 242. The connections external to the first die 220 are as shown as in FIG. 3A.

The bonding wire 242 has a parasitic inductor 315 with a parasitic inductance Lₚ₁. The portion of the inductor circuit 240 inside the first die 220 includes capacitors 342, 344, 352, and 358 and resistors 354 and 356. All capacitors are modeled capacitors from the corresponding circuits. The capacitor 342 represents the capacitance at the pad 225 due to a voltage difference exists between the pad and nearby conductors (e.g., traces). It is a parasitic capacitance because it's not intentionally designed, but rather a natural byproduct of the conductor's geometry and proximity to other conductors. The capacitor 344 is a modeled capacitor from an electrostatic discharge (ESD) circuit. It is used so that the current path is available for all stress combinations between an I/O pad and internal grounds. It absorbs energy without destroying the internal circuitry. The capacitor 352 is due to the transmitter at port 1. The capacitor 358 is due to the receiver at port 2. The resistor 354 is a resistor used for on-die termination (ODT). It is a termination resistor integrated directly into the first die 220 to control signal reflections by impedance matching. The ODT resistor 354 is controllable, meaning its functionality can be dynamically enabled or disabled, allowing for optimal signal integrity based on the specific needs of the circuit at any given time. The resistor 356 is a resistor used in a charge device model (CDM) when an ESD event occurs. Together, the inductor 340, the capacitors 342, 344, 352, and 358 and the resistors 354 and 356 form a network to act like a component (e.g., a resonator) that reduces high-frequency distortions and improves signal integrity.

The inductor 340 is placed between the transmitter port 1 and the receiver port 2 and is connected to the die first pad 225 via the ESD capacitor 344. It has a first inductance of L₁. The signal path for the connection configuration shown in FIGS. 3A and 3B is the path 325. This path goes through the inductor 340 and the resistor 356 to the receiver port 2. The effective inductance is therefore equal to L₁. The inductance L₁ provides an effective inductance to improve signal integrity. Let L_{eff} be the effective inductance for the inductor circuit 240. For the connection configuration where the inductor 340 is placed between the transmitter 320 and the receiver 330, the effective inductance is given by equation (1) as follows.

$${L}_{eff} = {L}_{1} \qquad ( 1 )$$

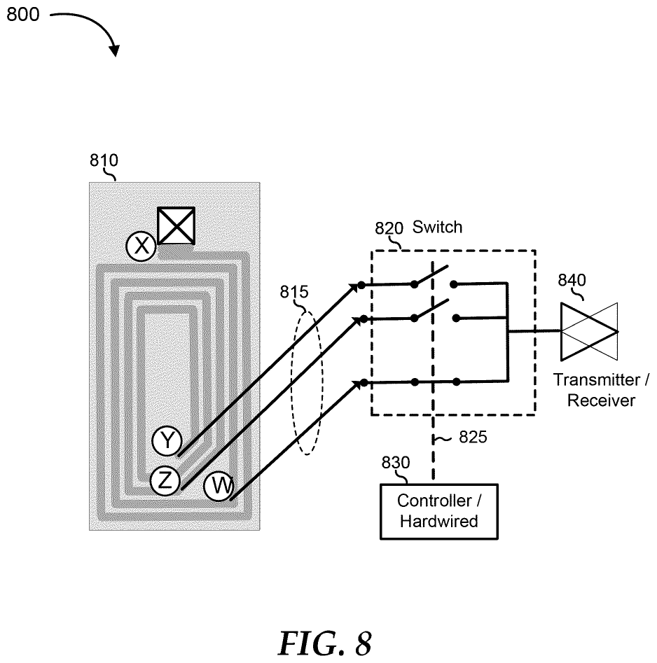

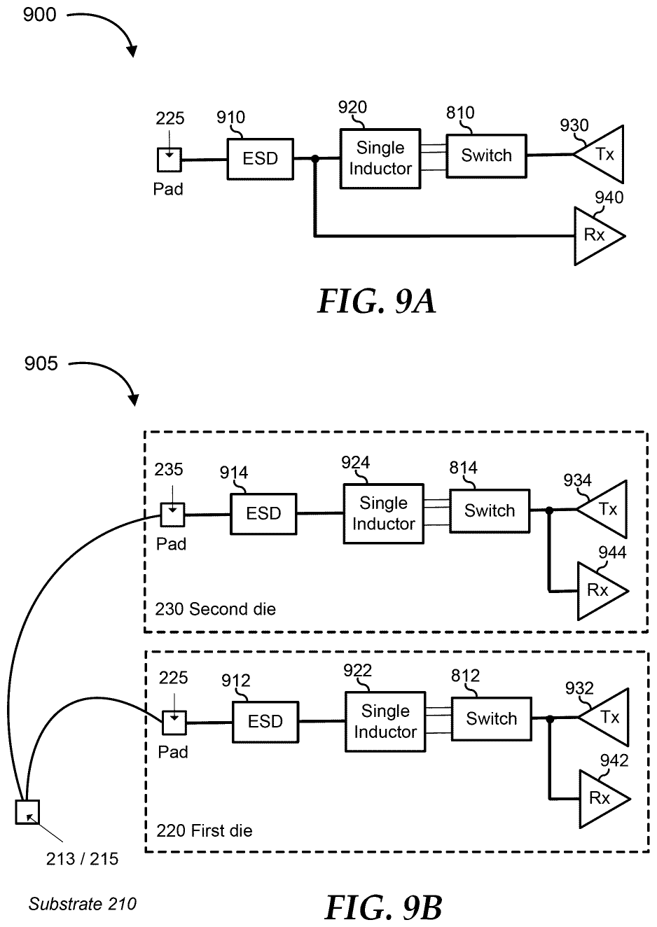

Accordingly, by selecting a proper value of L₁, the inductor circuit 240 may be able to reduce distortions caused by the transmission losses. Such a value may be determined through SI simulation. After fabrication, it may be determined through testing and measurements for compensation of process variation. The inductance L₁ may be adjusted in-circuit using an electronic fuse switch. This will be discussed further in FIGS. 8 and 9A.

For stacked dies, there may be two connection patterns or configurations for the inductor circuit 240. One is a direct bonding connection, and one is a cascade connection.

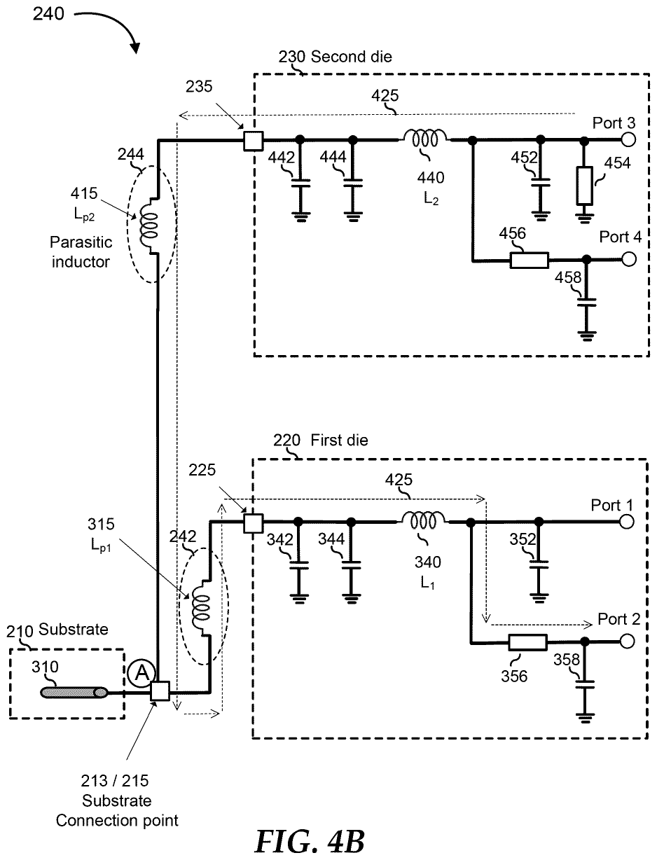

FIG. 4A is a diagram illustrating a direct bonding connection in a die-stacked package according to an embodiment. In this connection configuration, the second die 230 is stacked on top of the first die 220. The bonding wires 242 and 244 are connected to the first die 220 and the second die 240 from the same connection point on the substrate. The same connection configuration can be extended to more than two stacked dies.

The bonding wire 242 connects the substrate pad 213 or 215 to the die first pad 225 as in the configuration shown in FIG. 3A. The bonding wire 244 connects the same substrate pad 213 or 215 to the die second pad 235. The substrate pads 213 and 215 are connected together to become a substrate connection point A. The second die 230 has a transmitter 420 at port 3 and receiver 430 at port 4. A path 425 is a signal reflection path from ODT to receiver. When we want to write a signal to the first die 220 and if we turn on ODT at the second die 230, then there is a signal traveling path 425 from the port 3 with ODT to the receiver port 2. This is referred to as non target ODT. It is some reflection path from ODT to the receiver. In this two-stack die (or 2-rank, 1 signal from host connected to 2 dies) case, unlike the one-die stack case, the parasitic inductance of wire bonding can be utilized as effective inductance through a signal traveling path 425. When we want write a signal to first die 220 and if we turn on ODT at first die 220, there is no signal reflection path like 425. We call this target ODT. In this case, we cannot utilize the parasitic inductance of wire bonding like one-die stack shown in FIG. 3B.

FIG. 4B is a diagram illustrating the inductor circuit 240 shown in FIG. 2 using the direct bonding connection shown in FIG. 4A in a die-stacked package according to an embodiment. The connection pattern or configuration in the inductor circuit 240 follows that shown in FIG. 4A.

The bonding wire 242 is the same as described in FIG. 3B. It has a parasitic inductor 315 with a parasitic inductance of Lₚ₁. The bonding wire 244 has a parasitic inductor 415 with a parasitic inductance of Lₚ₂. It may be a little longer than the bonding wire 242 because it has to connect to the second die 230 which is bonded on top of the first die 220 and is located farther from the substrate connection point A. The parasitic inductance Lₚ₂ is therefore different from, or larger than, Lₚ₁. The first die 220 has the same components as shown in FIG. 3B. Therefore, the description will not be repeated. The only component that is not present is the ODT resistor 354 because port 1 is not used as a transmitter in this configuration. As the ODT resistor 354 is controllable, it is simply disabled so that it does not affect the performance of the signal transmission. The second die 230 has components that are similar to those shown in FIG. 3B and their descriptions follow those in FIG. 3B. The inductor 440 is similar to the inductor 340 in the first die 220. The inductor 440 has a second inductance L₂. In one embodiment, the second inductance is equal to the first inductance. The capacitors 442, 444, 452, and 458 are similar to the capacitor 342, 344, 352, and 358, respectively. Similarly, the resistors 454 and 456 are similar to the resistors 354 and 356, respectively. Therefore, their descriptions will not be repeated.

The signal path 425 starts from the transmitter port 3 with ODT 454 and goes through the second inductor 440, the parasitic inductor 415, the parasitic inductor 315, and the first inductor 425 to the receiver port 2. Since these inductors are connected in series, the equivalent inductance is equal to the sum of the individual inductances. Therefore, the effective L_{eff} for the direct bonding connection is given by equation (2) as follows.

$${L}_{eff} = {L}_{1} + {L}_{2} + {L}_{p 1} + {L}_{p 2} \qquad ( 2 )$$

As noted earlier, L₂ may be equal to L₁, and equation (2) may be rewritten as:

$${L}_{eff} = 2 {L}_{1} + {L}_{p 1} + {L}_{p 2} \qquad ( 3 )$$

The relative values of Lₚ₁ and Lₚ₂ with respect to L₁, L₁ depend on the length of wire, diameter, material and frequency.

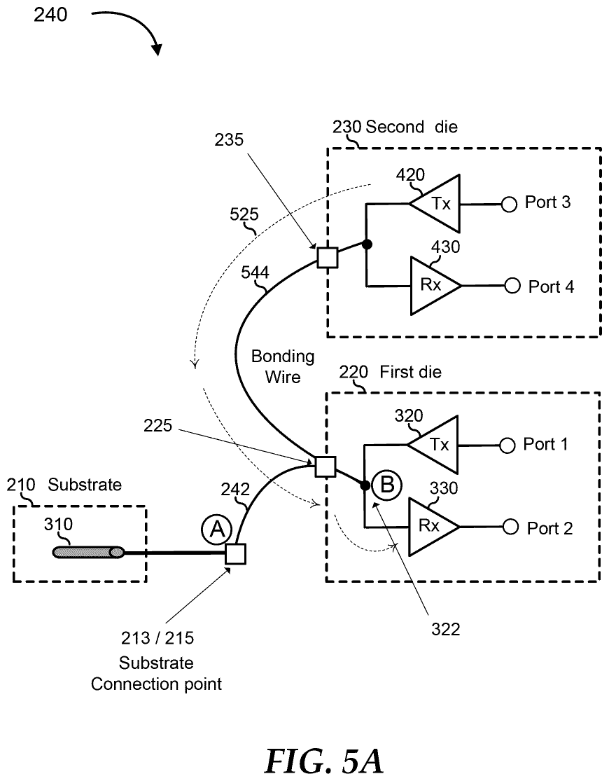

FIG. 5A is a diagram illustrating a cascade connection for the inductor circuit 240 shown in FIG. 2 in a die-stacked package according to an embodiment. The cascade connection configuration differs from the direct bonding connection in that the second die 230 is connected in a cascade manner. The same connection can be extended to more than two stacked dies.

The bonding wire 242 connects the substrate pad 213 or 215 on the substrate at the substrate connection point A to the die first pad 225. The die first pad 225 is directly connected to a connection point B in the first die 220. The bonding wire 544 connects the die first pad 225 to the die second pad 235. It has a parasitic inductor 515 having a parasitic inductance Lₚ₃. Since the distance from the die first pad 225 to the die second pad 235 is shorter than the distance from the substrate connection point A to the die second pad 235, the length of the bonding wire 544 is shorter than the length of the bonding wire 244 shown in FIGS. 4A and 4B. Accordingly, the inductance Lₚ₃ of the parasitic inductor 515 is different from that of the parasitic inductor 415. Signals travel from the transmitter port 3 in the second die 230 to the receiver port 2 in the first die 220 via a signal path 525. The path 525 bypasses the bonding wire 242 and goes directly to the connection point B in the first die 220.

FIG. 5B is a diagram illustrating the inductor circuit 240 shown in FIG. 2 using the cascade connection shown in FIG. 4A in a die-stacked package according to an embodiment. The components in the first die 220 and the second die 230 in FIG. 5B are the same corresponding components in FIG. 4B. Therefore, their descriptions will not be repeated. The main difference is the connections of the bonding wire 242 and the bonding wire 544. This connection is described in FIG. 5A.

The signal path 525 starts from the transmitter port 3, going through the second inductor 440, the parasitic inductor 515, and the first inductor 340. It bypasses the parasitic inductor 315. As in the case of FIG. 4B, the equivalent inductance of the inductor circuit 240 is equal to the sum of the above inductances. Therefore, the effective L_{eff} for the cascade bonding connection is given by equation (2) as follows.

$${L}_{eff} = {L}_{1} + {L}_{2} + {L}_{p 3} \qquad ( 4 )$$

As noted earlier, L₂ may be equal to L₁, and equation (4) may be rewritten as:

$${L}_{eff} = 2 {L}_{1} + {L}_{p 3} \qquad ( 5 )$$

The relative value of Lₚ₃ with respect to L₁ depends on the length of wire, diameter, material and frequency.

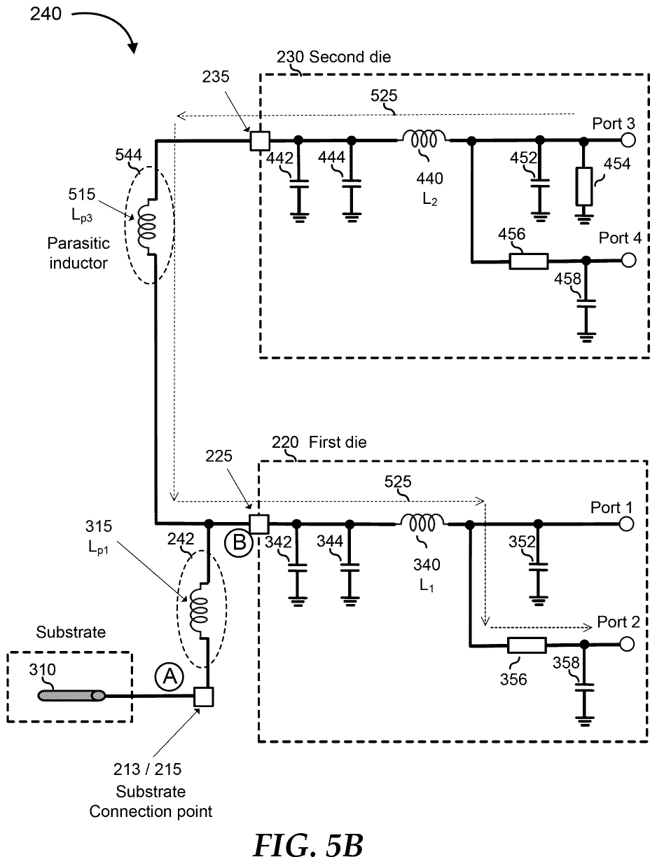

FIG. 6 is a diagram illustrating performance curves 600 as functions of inductance at various data rates according to an embodiment. These curves correspond to the cascade connection shown in FIGS. 5A and 5B. The performance curves 600 are produced as a result of simulation. The values are estimated. The results do not represent accurate quantitative measurements, but they reflect the qualitative interpretation of the performance of the inductor circuit 20 as a function of the inductance L₁. The performance is evaluated by the EH value. The “EH” stands for “Eye Height,” which is a critical metric used to assess the quality of a transmission signal by measuring the vertical distance between the high and low logic levels within an “eye diagram,” essentially indicating how well the signal can be reliably interpreted by the receiver. A larger EH signifies better signal integrity. The performance curves 600 are plotted in a coordinate system having the abscissa (the horizontal axis) representing the inductance L₁ (in nano Henry, nH) ranging from 0 nH to 2.0 nH, and the ordinate (the vertical axis) representing the EH (in Volt) ranging from −0.1 V to 0.2 V.

The performance curves 600 include characteristic curves 610, 620, 630, and 640. The curves 610, 620, 530, and 640 correspond to the data rates of 6 Gbps (Giga bits per second), 10 Gbps, 12 Gbps, and 16 Gbps, respectively. The optimal point is the peak or the maximum value of the curve because it corresponds to the highest value of the EH. The curve 610 appears flat with no obvious optimal point. The curve 620 has an optimal point M₁ at L₁=1.0 nH. The curve 630 has an optimal point at M₂ at L₁=0.9 nH. The curve 640 has an optimal point M₃ at L₁=0.8 nH. As the data rate or frequency (f) increases, the optimal value of L₁ decreases according to the equation: f=1/[2π*sqrt (LC)]. In addition, for the same data rate, the signal integrity, as measured by EH, increases as L₁ increases but only up to an optimal value. From that on, increasing L₁ decreases the signal integrity.

Based on these curves, it is noted that the value of the inductance L₁ has a significant effect on signal integrity. The signal integrity of a propagating signal in a stacked-die package is a function of the inductance L₁. Accordingly, it is desirable to be able to adjust the value of L₁ according to the electrical characteristics of the operational environment. This adjustment may be made using an electronic fuse (eFuse) in the form of a switch as shown in FIGS. 8, 9A, and 9B.

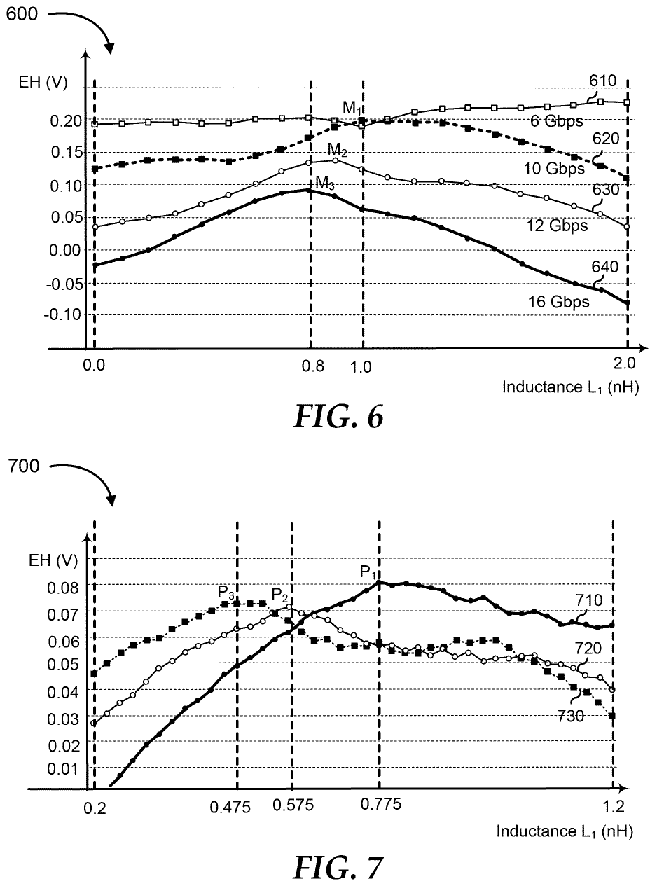

FIG. 7 is a diagram illustrating performance curves 700 as functions of inductance at various connection configurations according to an embodiment. These curves correspond to the directing bonding and cascade connections shown in FIGS. 4A, 4B, 5A and 5B. As in FIG. 6, the performance curves 700 are produced as a result of simulation. The values are estimated. The performance curves 700 include the characteristic curves 710, 720, and 730. The performance curves 700 are plotted in a coordinate system having the abscissa ranging from 0.2 nH to 1.2 nH, and the ordinate ranging from 0.01 V to 0.02 V.

The curve 710 corresponds to the cascade bonding connection with bonding wires of normal lengths. It has an optimal point P₁ at L₁=0.775 nH. The curve 720 corresponds to the direct bonding connection with bonding wires of normal lengths. It has an optimal point P₂ at L₁=0.575 nH. The curve 730 corresponds to the direct bonding connection with bonding wires of longest lengths. It has an optimal point P₃ at L₁=0.475 nH to 0.525 nH.

The cascade bonding connection has a better performance than the direct bonding connection with a higher value of L₁. P₁ is at EH=0.08 V while P₂ is at EH=0.07. Accordingly, the signal integrity appears to be increased about 14% from direct bonding to cascade bonding. But if we want to have smaller L₁ inductance and small area, the curve 730 is the best. It can improve SI about 53% form 0.047V with no coil to 0.072V with coil. The curves 720 and 730 show that they have similar EH values but with different inductance values. The curve 730 has the optimal inductance L₁=0.475 nH to 0.525 nH while the curve 720 has the inductance L₁=0.575.

The curves in FIGS. 6 and 7 show that the performance of the inductor circuit 240 depends on the value of the inductance in the inductors 340 and 440. Therefore, it is desirable to be able to adjust this inductance according to the operational conditions such as die and substrate geometry, wire characteristics (length, material, etc.). One way to do this is to use a switch.

FIG. 8 is a diagram illustrating a configuration 800 of an inductor with a switch to adjust inductance according to an embodiment. The configuration 800 includes an inductor 810, a switch 820, a control functionality 830 and a transmitter/receiver 840.

The inductor 810 is a coil like the inductor 340 or 440. It has a connection point X on one end and three connection points Y, Z, and W that determine the other end of the coil. The switch 820 is an electronic switch such as an electronic fuse (eFuse). The switch can be controlled to close or open by the control line 825 connected to a control functionality 830. The control functionality 830 may be a controller circuit or a hardwired configuration. By closing a switch and opening the others, the length of the coil is changed, which changes the inductance value. One can primarily adjust the number of turns of wire on the coil, as increasing the number of turns directly increases the inductance. The transmitter or receiver 840 is a starting or end point on the signal path.

FIG. 9A is a diagram illustrating a configuration 900 of an inductor circuit with switch in a single-die package according to an embodiment. The configuration 900 includes the die first pad 225, an ESD circuit 910, a single inductor 920, a switch 810, a transmitter 930, and a receiver 940.

The pad 225 is described in FIG. 2. The switch 810 is described in FIG. 8. The ESD circuit 910 may be modeled as an ESD capacitor similar to the capacitor 342 in FIG. 3B. The single inductor 920 is similar to the inductor 340 in FIG. 3B. The transmitter 930 and the receiver 940 are similar to the transmitter 320 and the receiver 330, respectively in FIG. 3A. The switch 810 is placed between the single inductor 920 and the transmitter 930. When the switch 810 is set according to a control functionality, it will activate a set switch to connect to the single inductor 920. The result is an inductor with a desired length and inductance.

FIG. 9B is a diagram illustrating a configuration 905 of an inductor circuit with switch in a die-stacked package according to an embodiment. The configuration 905 includes the components similar to those in FIG. 4B or 5B. The description in FIG. 9A may be applied here. The first die 220 includes a pad 225, an ESD circuit 912, a single inductor 922, a switch 812, a transmitter 932, and a receiver 942. The second die 230 includes a die second pad 235, an ESD circuit 914, a single inductor 924, a switch 814, a transmitter 934 and a receiver 944.

The above components are similar to the components in FIG. 9A and therefore no descriptions will be repeated. The ESD circuits 912 and 914 are similar to the ESD circuit 910. The single inductors 922 and 924 are similar to the single inductor 920. The switches 812 and 814 are similar to the switch 810. The transmitters 932 and 934 are similar to the transmitter 930. The receivers 942 and 944 are similar to the receiver 940. Though the configuration 905 shows a direct bonding connection, it may be extended to the cascade bonding configuration.

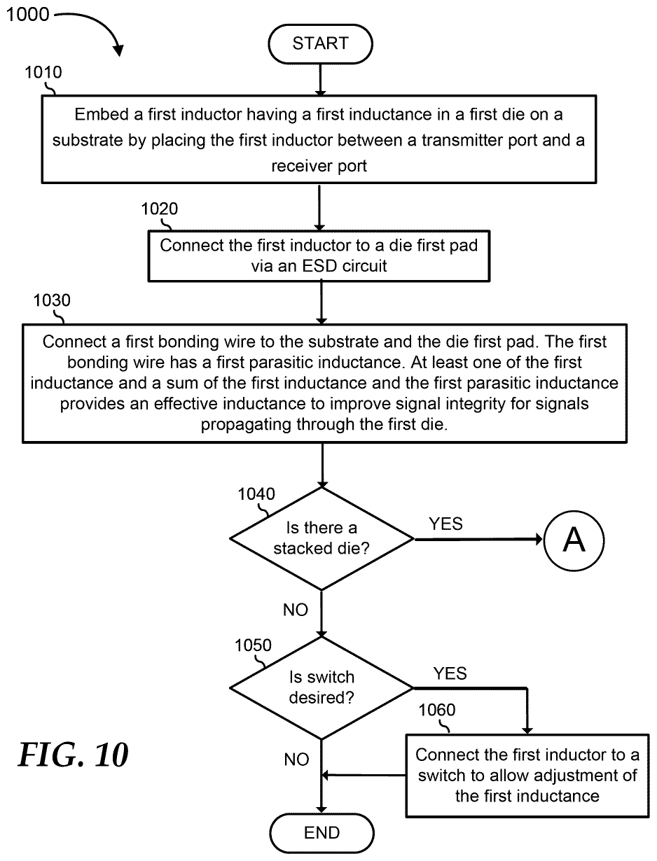

FIG. 10 is a flowchart illustrating a first part of a process 1000 of connecting an inductor circuit according to an embodiment.

Upon START, the process 1000 embeds a first inductor in a first die bonded to a substrate (Block 1010). This may be done by placing the first inductor between a transmitter port and a receiver port. The first inductor has a first inductance. Next, the process 1000 connects the first inductor to the die first pad via an electrostatic discharge (ESD) circuit (Block 1020). Then, the process 1000 connects a first bonding wire to the substrate and to the die first pad (Block 1030). The first bonding wire has a first parasitic inductance. At least one of the first inductance and a sum of the first inductance and the first parasitic inductance contributes to an effective inductance to improve signal integrity for signals propagating through the die.

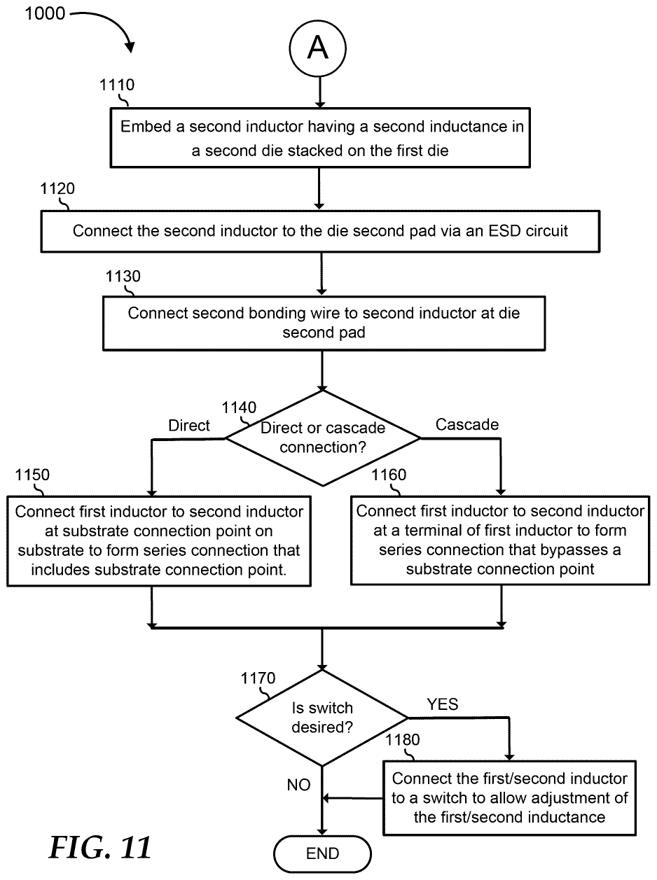

Next, the process 1000 determines if there is a stacked die (Block 1040). If so, the process 1000 proceeds to the continuation point A which will be shown in FIG. 11. If there is no stacked die, the process 1000 determines if a switch is desired (Block 1030). If not, the process 1000 is terminated. Otherwise, it is desired to have the switch, the process 1000 connects the first inductor to a switch to allow adjustment of the first inductance (Block 1060) and is then terminated.

FIG. 11 is a flowchart illustrating a second part of the process 1000 of connecting an inductor circuit according to an embodiment.

Upon continuing at A, the process 1000 embeds a second inductor having a second inductance in a second die stacked on the first die (Block 1110). Next, the process 1000 connects the second inductor to the die second pad via an ESD circuit (Block 1120). Then, the process 1000 connects a second bonding wire to the second inductor at the die second pad (Block 1130). The second bonding wire has a second parasitic inductance.

Next, the process 1000 determines if the connection of the bonding wires is a direct bonding connection or a cascade bonding connection (Block 1140). If it is a direct bonding connection, the process 1000 connects the first inductor to the second inductor via the first and second bonding wires at a substrate connection point on the substrate to form a series connection between the first inductor and the second inductor that includes the substrate connection point (Block 1150). The effective inductance is equal to a sum of the first inductance, the second inductance, the first parasitic inductance, and a second parasitic inductance. Then the process 1000 proceeds to block 1170. If it is a cascade bonding connection, the process 1000 connects the first inductor to the second inductor via the second bonding wire at a terminal of the first inductor to form a series connection between the first inductor and the second inductor that bypasses a substrate connection point on the substrate (Block 1160). The effective inductance is equal to the sum of the first inductance, the second inductance, and the second parasitic inductance.

Next, the process 1000 determines if it is desired to have a switch (Block 1170). If not, the process 1000 is terminated. Otherwise, the process 1000 connects the first inductor and the second inductor to a switch to allow adjustment of a corresponding inductance (Block 1180) and is then terminated.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. An apparatus comprising:
a first inductor configured to be embedded in a first die bonded to a substrate; and
a first bonding wire configured to connect the substrate to a die first pad of the first die, the first bonding wire having a first parasitic inductance,
wherein the first inductor has a first inductance, and
wherein at least one of the first inductance and a sum of the first inductance and the first parasitic inductance contributes to an effective inductance to improve signal integrity for signals propagating through the first die.

2. The apparatus of claim 1, wherein the first inductor is placed between a transmitter port and a receiver port and is connected to the die first pad via an electrostatic discharge (ESD) circuit modeled as an ESD capacitor.

3. The apparatus of claim 1, further comprising a second inductor having a second inductance and configured to be embedded in a second die stacked on the first die.

4. The apparatus of claim 3, further comprising a second bonding wire configured to connect to a die second pad, the second bonding wire having a second parasitic inductance.

5. The apparatus of claim 4, wherein the first inductor and the second inductor are connected in one of a direct bonding configuration and a cascade configuration.

6. The apparatus of claim 5, wherein in the direct bonding configuration, the first inductor and the second inductor are connected via the first and second bonding wires at a substrate connection point on the substrate to form a series connection between the first inductor and the second inductor that includes the substrate connection point.

7. The apparatus of claim 6, wherein the effective inductance is equal to a sum of the first inductance, the second inductance, the first parasitic inductance, and the second parasitic inductance.

8. The apparatus of claim 5, wherein in the cascade configuration, the first inductor and the second inductor are connected via the second bonding wire at a terminal of the first inductor to form a series connection between the first inductor and the second inductor that bypasses a substrate connection point on the substrate.

9. The apparatus of claim 8, wherein the effective inductance is equal to a sum of the first inductance, the second inductance, and the second parasitic inductance.

10. The apparatus of claim 3, wherein at least one of the first inductor and the second inductor is connected to a switch to allow adjustment of a corresponding inductance.

11. A method comprising:
embedding a first inductor in a first die bonded to a substrate;
connecting the first inductor to a die first pad; and
connecting a first bonding wire to the substrate and to the die first pad, the first bonding wire having a first parasitic inductance,
wherein the first inductor has a first inductance, and
wherein at least one of the first inductance and a sum of the first inductance and the first parasitic inductance contributes to an effective inductance to improve signal integrity for signals propagating through the die.

12. The method of claim 11, wherein embedding the first inductor comprises placing the first inductor between a transmitter port and a receiver port, and
wherein connecting the first inductor comprises connecting the first inductor to the die first pad via an electrostatic discharge (ESD) circuit modeled as an ESD capacitor.

13. The method of claim 11, further comprising embedding a second inductor having a second inductance in a second die stacked on the first die.

14. The method of claim 13, further comprising connecting a second bonding wire to the die second pad, the second bonding wire having a second parasitic inductance.

15. The method of claim 14, wherein the first inductor and the second inductor are connected in one of a direct bonding configuration and a cascade configuration.

16. The method of claim 15, wherein in the direct bonding configuration, the first inductor and the second inductor are connected via the first and second bonding wires at a substrate connection point on the substrate to form a series connection between the first inductor and the second inductor that includes the substrate connection point.

17. The method of claim 16, wherein the effective inductance is equal to a sum of the first inductance, the second inductance, the first parasitic inductance, and a second parasitic inductance.

18. The method of claim 15, wherein in the cascade configuration, the first inductor and the second inductor are connected via the second bonding wire at a terminal of the first inductor to form a series connection between the first inductor and the second inductor that bypasses a substrate connection point on the substrate.

19. The method of claim 18, wherein the effective inductance is equal to a sum of the first inductance, the second inductance, and a second parasitic inductance.

20. A system comprising:
a first die having a die first pad and bonded to a substrate; and
an inductor circuit comprising:
a first inductor configured to be embedded in the first die and connected to the die first pad; and
a first bonding wire configured to connect the substrate to the die first pad, the first bonding wire having a first parasitic inductance,
wherein the first inductor has a first inductance, and
wherein at least one of the first inductance and a sum of the first inductance and the first parasitic inductance contributes to an effective inductance to improve signal integrity.
